(19) United States
(12) Patent Application Publication
(10) Pub. No.: US 2013/0026896 A1
(43) Pub. Date: Jan. 31, 2013

(54) ASSEMBLY STRUCTURE FOR ASSEMBLING PANEL MODULES WITH DIFFERENT SIZES AND PANEL DEVICE THEREWITH

(71) Applicants: Shou-Lun Chang, New Taipei City (TW); Feng-Yun Wu, New Taipei City (TW)

(72) Inventors: Shou-Lun Chang, New Taipei City (TW); Feng-Yun Wu, New Taipei City (TW)

(21) Appl. No.: 13/414,700

(22) Filed: Mar. 7, 2012

(30) Foreign Application Priority Data
Jul. 25, 2011 (CN) 201110208338.2

(51) Int. Cl. A47B 96/20; H05K 13/04

(52) U.S. Cl. 312/237; 29/729

(57) ABSTRACT

An assembly structure includes a panel installing member, a back cover, a first frame component and a second frame component. The panel installing member is used for holding a first panel module, and a plurality of assembly holes is formed on the panel installing member. The back cover includes a plurality of posts, and each of the posts is disposed through the corresponding assembly hole. The first frame component is installed on the back cover for being selectively fixed on a side of the panel installing member or on a side of a second panel module. The second frame component is installed on the back cover for being selectively fixed on another side of the panel installing member or on another side of the second panel module, so as to fix the first panel module or the second panel module on the back cover cooperatively with the first frame component.

### BACKGROUND OF THE INVENTION

1. Field of the Invention

The present invention relates to an assembly structure and a related panel device, and more particularly, to an assembly structure for assembling panel modules with different sizes and a related panel device.

2. Description of the Prior Art

With development of technology, a notebook computer is considered one of the most important necessities in most people's daily life and is used for dealing with documenting affairs, playing films, playing video games and so on. In process of manufacture, the notebook computer needs different panel modules with different specifications, such as different sizes to yield to a vendor's ability, product specification and so on. However, the different panel modules can not be installed on the same back cover of the notebook computer since sizes, structures and so on of the different panel modules are different from each other. Accordingly, it results in difficulty for the different panels to be installed on the same back cover. Thus, it is required to adapt the different back covers to the different panel modules. In practical application, it needs a plurality of tooling to manufacture the above-mentioned back covers, so as to greatly increase manufacturing cost and to result in disadvantage of the product in price.

### SUMMARY OF THE INVENTION

The present invention provides an assembly structure for assembling panel modules with different sizes and a related panel device for solving above drawbacks.

According to the claimed invention, an assembly structure for selectively assembling a first panel module and a second panel module with different sizes includes a panel installing member, a back cover, a first frame component and a second frame component. The panel installing member is used for holding a first panel module, and a plurality of assembly holes is formed on the panel installing member. The back cover includes a plurality of posts, and each of the posts is disposed through the corresponding assembly hole. The first frame component is installed on the back cover for being selectively fixed on a side of the panel installing member or on a side of a second panel module. The second frame component is installed on the back cover for being selectively fixed on another side of the panel installing member or on another side of the second panel module, so as to fix the first panel module or the second panel module on the back cover cooperatively with the first frame component.

According to the claimed invention, the first frame component and the second frame component are screwed on the back cover, respectively.

According to the claimed invention, the first frame component and the second frame component are screwed on the panel installing member or on the second panel module, respectively.

According to the claimed invention, the plurality of posts is fixed inside the plurality of assembly holes in a hot melting manner, respectively.

According to the claimed invention, a panel device includes a first panel module and an assembly structure for assembling the first panel module. The assembly structure includes a panel installing member, a back cover, a first frame component and a second frame component. The panel installing member is used for holding a first panel module, and a plurality of assembly holes is formed on the panel installing member. The back cover includes a plurality of posts, and each of the posts is disposed through the corresponding assembly hole. The first frame component is installed on the back cover for being selectively fixed on a side of the panel installing member or on a side of a second panel module. The second frame component is installed on the back cover for being fixed on another side of the panel installing member or on another side of the second panel module, so as to fix the first panel module or the second panel module on the back cover cooperatively with the first frame component.

According to the claimed invention, the first frame component and the second frame component are screwed on the panel installing member, respectively.

In summary, when installing the first panel module, the assembly structure of the present invention utilizes the panel installing member, the first frame component and the second frame component to fix the first panel module on the back cover. On the other hand, when installing the second panel module with different size, the assembly structure of the present invention only utilizes the first frame component and the second frame component, without utilizing the panel installing member, to fix the second panel module on the back cover. In such a manner, the assembly structure of the present invention allows the first panel module or the second panel module to be installed on the same back cover by selectively utilizing the panel installing member. In other words, the panel installing member can be an assembly structure for the panel modules with different sizes. Accordingly, the first panel module and the second panel module of the panel device of the present invention can be installed on the same back cover. In practical application, the present invention can prevent a plurality of tooling from manufacturing, so as to greatly reduce manufacturing costs and to result in advantage of the product in price.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a portable electronic device according to an embodiment of the present invention.

FIG. 2 is an assembly diagram of a panel device according to the embodiment of the present invention.

FIG. 3 is an exploded diagram of the panel device according to the embodiment of the present invention.

FIG. 4 is a partially exploded diagram of a panel installing member, a first frame component and a back cover according to the embodiment of the present invention.

FIG. 5 is a partially exploded diagram of the panel installing member, a second frame component and the back cover according to the embodiment of the present invention.

FIG. 6 is a diagram of the panel installing member, the first frame component and the second frame component according to the embodiment of the present invention.

FIG. 7 is an exploded diagram of the first frame component screwed on the panel installing member cooperatively with the second frame component and the back cover in FIG. 6.

FIG. 8 is an assembly diagram of the components in FIG. 7.

FIG. 9 is a diagram of the first frame component, the second frame component and a second panel module according to the embodiment of the present invention.

FIG. 10 is an exploded diagram of the first frame component, the second frame component and the second panel module according to the embodiment of the present invention.

FIG. 11 is an exploded diagram of the first frame component screwed on the second panel module cooperatively with the second frame component and the back cover in FIG. 9.

FIG. 12 is an assembly diagram of the components in FIG. 11.

### DETAILED DESCRIPTION

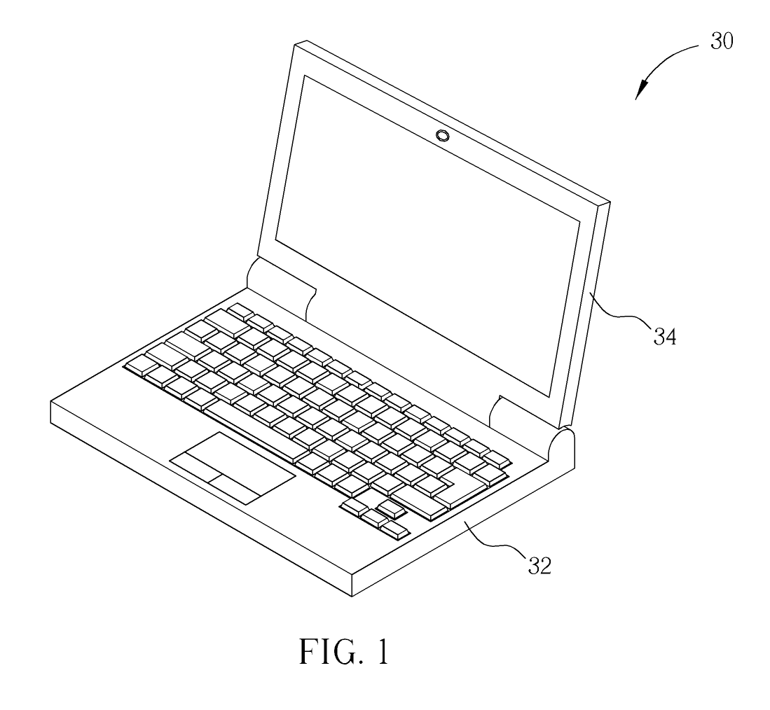

Please refer to FIG. 1. FIG. 1 is a diagram of a portable electronic device 30 according to an embodiment of the present invention. As shown in FIG. 1, the portable electronic device 30 includes a host device 32 and a panel device 34. In this embodiment, the portable electronic device 30 can be preferably a notebook computer, the host device 32 can be a notebook computer host equipped with components such as a mainboard, an optical disk device, a hard disk drive and so on, and the panel device 34 can be a notebook computer panel module equipped with components such as a display panel, a backlight module and so on.

Furthermore, the panel device 34 is pivoted at the host device 32, such that the panel device 34 can be opened or closed relative to the host device 32. Accordingly, when the panel device 34 is opened relative to the host device 32, the portable electronic device 30 can be used for dealing with documenting affairs, playing films, playing video games and so on. On the other hand, when the panel device 34 is closed relative to the host device 32, the portable electronic device 30 is capable of being easily contained and carried. It should be noticed that application of the panel device 34 of the present invention is not limited to those mentioned in this embodiment. For example, the panel device 34 can be a liquid crystal display device implemented in a desktop computer or other portable electronic devices, such as a Personal Digital Assistant (PDA), a portable electronic translator and so on.

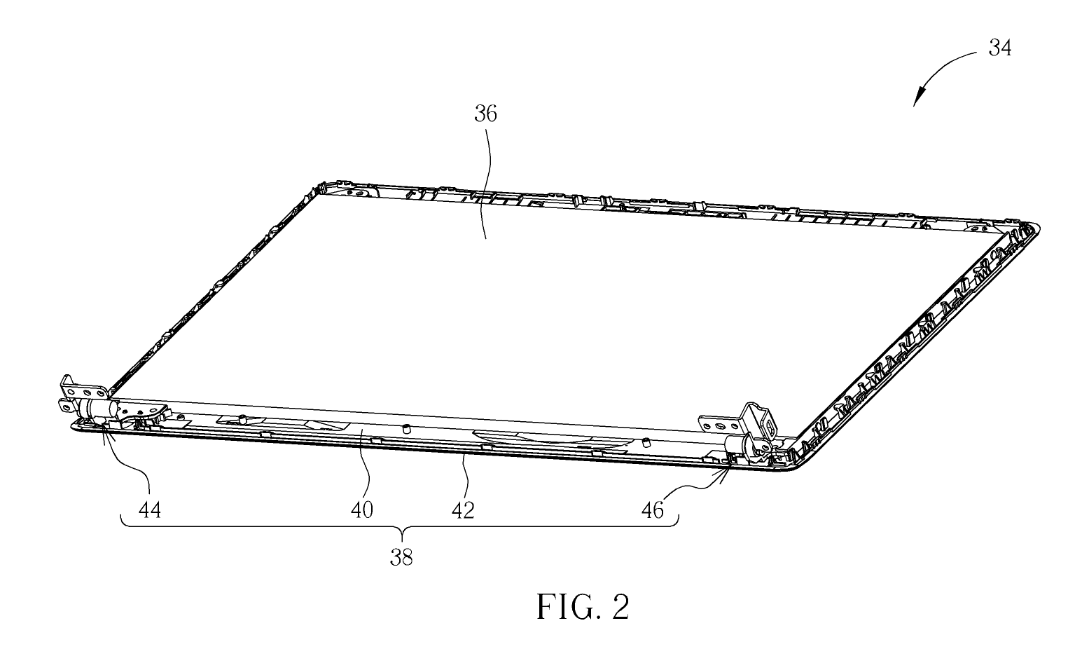

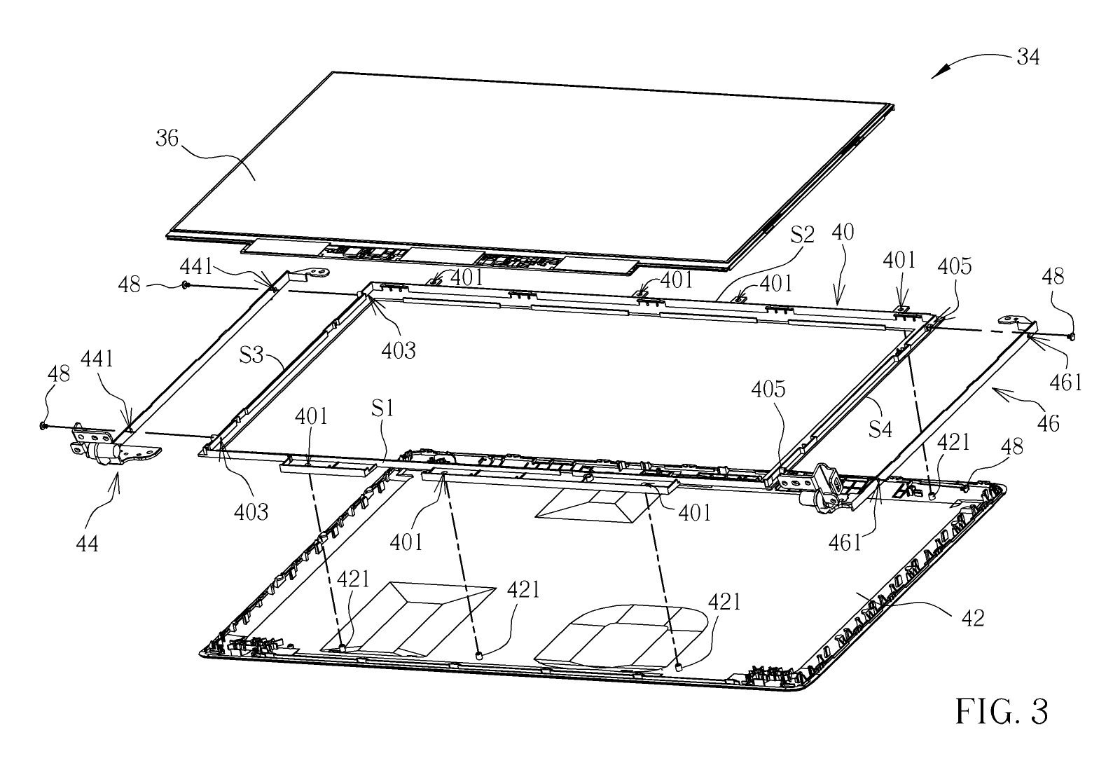

Please refer to FIG. 2 and FIG. 3. FIG. 2 is an assembly diagram of the panel device 34 according to the embodiment of the present invention. FIG. 3 is an exploded diagram of the panel device 34 according to the embodiment of the present invention. As shown in FIG. 2 and FIG. 3, the panel device 34 includes a first panel module 36 and an assembly structure 38. The assembly structure 38 can be used for assembling the first panel module 36. The assembly structure 38 includes a panel installing member 40, a back cover 42, a first frame component 44 and a second frame component 46. In this embodiment, the panel installing member 40 includes seven assembly holes 401. Three of the seven assembly holes 401 are formed on a first side S1 of the panel installing member 40, and the other four of the seven assembly holes 401 are formed on a second side S2 opposite to the first side S1 of the panel installing member 40. It should be noticed that amount and disposal position are not limited to those mentioned in this embodiment, and it depends on practical demands.

In addition, the back cover 42 includes a plurality of posts 421. Each of the posts 421 corresponds to each of the assembly holes 401 and is disposed through the corresponding assembly hole 401. In practical application, the posts 421 can be a hot melting post respectively, and the plurality of posts is respectively fixed inside the plurality of assembly holes 401 in a hot melting manner, so as to fix the back cover 42 and the first side S1 of the panel installing member 40 and to fix the back cover 42 and the second side S2 of the panel installing member 40, such that the panel installing member 40 can be fixed on the back cover 42.

In this embodiment, two screw holes 403 are formed on a third side S3 adjacent to the first side S1 and the second side S2 of the panel installing member 40, and two screw holes 405 are formed on a fourth side S4 opposite to the third side S3 of the panel installing member 40. Two through holes 441 on the first frame component 44, and each of the through holes 441 corresponds to each of the screw holes 403 on the third side S3. Two through holes 461 on the second frame component 46, and each of the through holes 461 corresponds to each of the screw holes 405 on the fourth side S4. Furthermore, the assembly structure 38 further includes four screws 48 corresponding to the through holes 441, 461 and the screw holes 403, 405. The screws 48 are used for being screwed with the screw holes 403 after being disposed through the through holes 441, and for being screwed with the screw holes 405 after being disposed through the through holes 461.

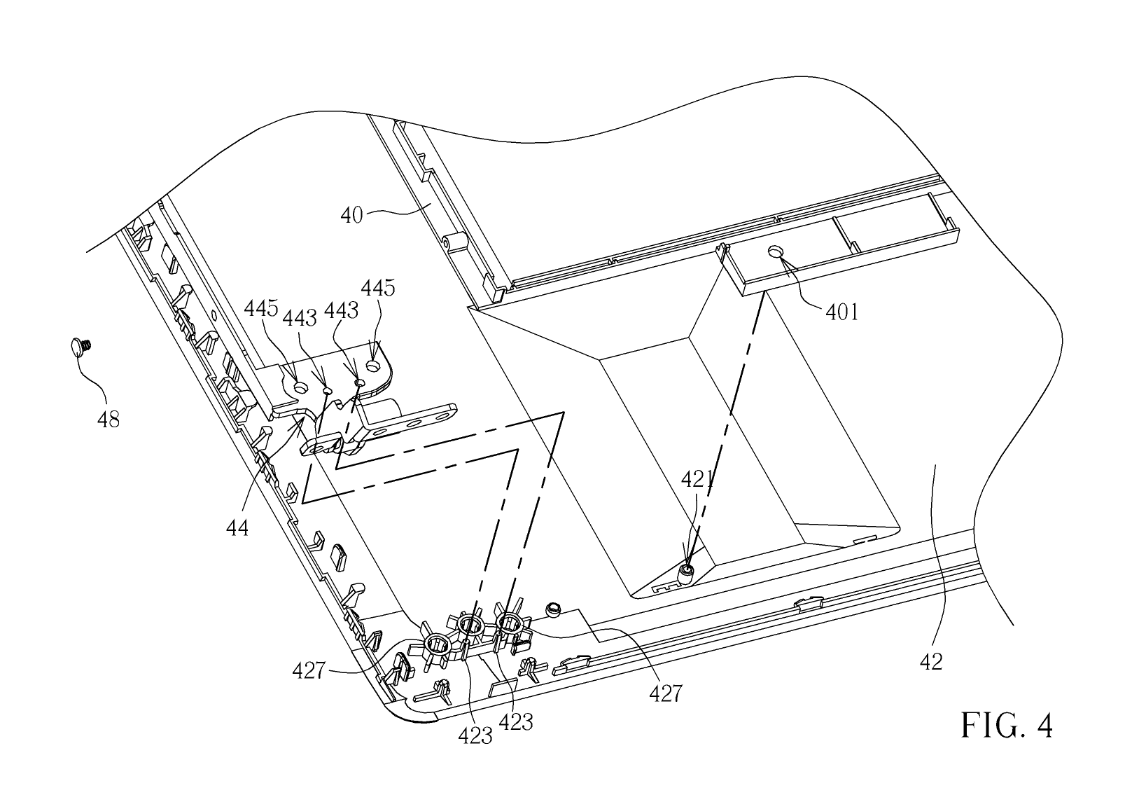

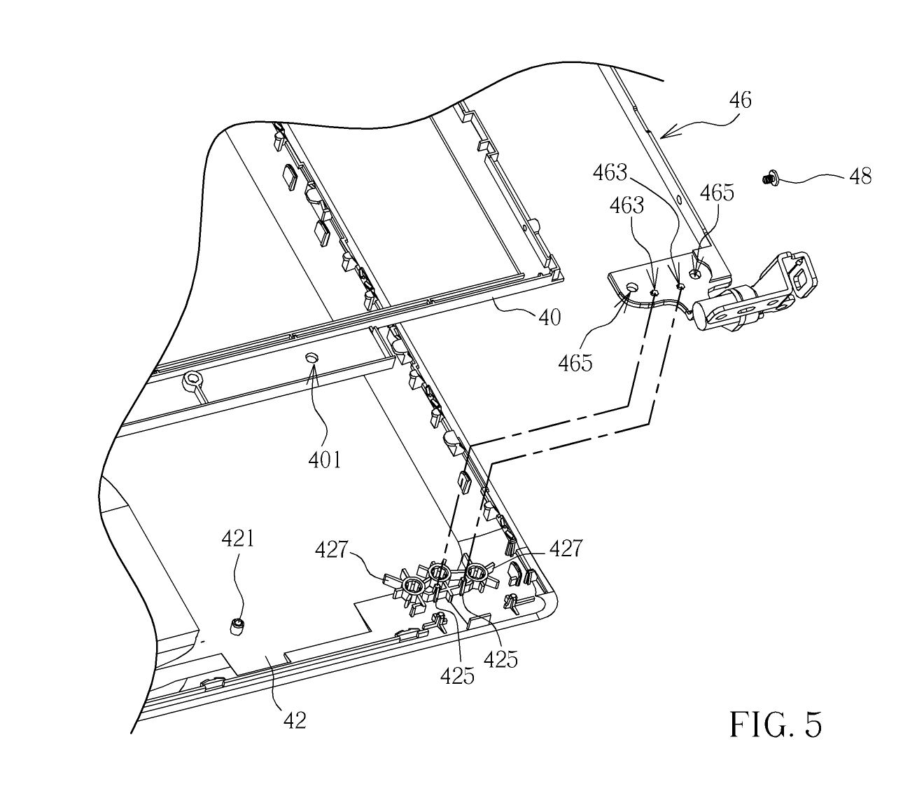

Please refer to FIG. 4 and FIG. 5. FIG. 4 is a partially exploded diagram of the panel installing member 40, the first frame component 44 and the back cover 42 according to the embodiment of the present invention. FIG. 5 is a partially exploded diagram of the panel installing member 40, the second frame component 46 and the back cover 42 according to the embodiment of the present invention. As shown in FIG. 4 and FIG. 5, the first frame component 44 has a first positioning portion 443 and at least one first fixing portion 445, and the second frame component 46 has a second positioning portion 463 and at least one second fixing portion 465. In this embodiment, the first frame component 44 includes two first fixing portions 445, so as to fix the first frame component 44 and the back cover 42 more firmly. Similarly, the second frame component 46 includes two second fixing portions 465, so as to fix the second frame component 46 and back cover 42 more firmly.

In practical application, the first positioning portion 443 of the first frame component 44 can be preferably a set of a round hole and a long-stripped hole. The round hole and the long-stripped hole of the first positioning portion 443 are respectively disposed through a corresponding first positioning post 423 on the back cover 42. Furthermore, the round hole is used for positioning the first frame component 44 and the back cover 42, and the long-stripped hole is used for preventing the first frame component 44 from rotating relative to the back cover 42. Similarly, the second positioning portion 463 of the second frame component 46 can be preferably a set of a round hole and a long-stripped hole as well. The round hole and the long-stripped hole of the second positioning portion 463 are respectively disposed through a corresponding second positioning post 425 on the back cover 42. Furthermore, the round hole is used for positioning the second frame component 46 and the back cover 42, and the long-stripped hole is used for preventing the second frame component 46 from rotating relative to the back cover 42.

Furthermore, the first fixing portion 445 of the first frame component 44 and the second fixing portion 465 of the second frame component 46 can be preferably a through hole, respectively. The through holes allow the first frame component 44 and the second frame component 46 to be respectively screwed on a screwing structure 427, e.g. a screwing boss on the back cover 42, by utilizing a screw (not shown in figures), respectively. Accordingly, the first frame component 44 and the second frame component 46 can be respectively pressed and fixed on a top surface of the screwing structure 427 by screw. In summary, the first frame component 44 and the second frame component 46 can be positioned on the back cover 42 by the first positioning portion 443 and the second positioning portion 463, respectively. Then, the first frame component 44 and the second frame component 46 can be fixed on the back cover 42 in the hot melting manner by the first fixing portion 445 and the second fixing portion 465, respectively. In such a manner, the first frame component 44 and the second frame component 46 can be installed on the back cover 42, respectively.

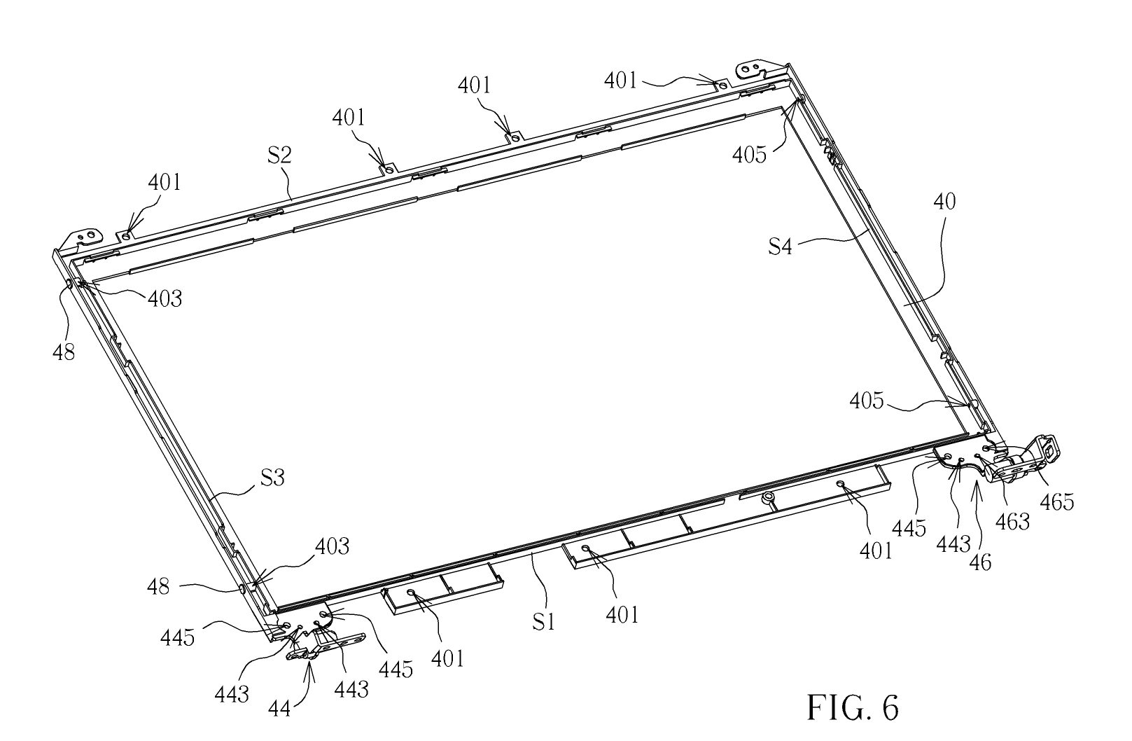

Please refer to FIG. 3 and FIG. 6. FIG. 6 is a diagram of the panel installing member 40, the first frame component 44 and the second frame component 46 according to the embodiment of the present invention. As shown in FIG. 3 and FIG. 6, when the first panel module 36 of the panel device 34 is assembled on production line, the screws 48 are disposed through the through holes 441 on the first frame component 44. Then, the screws 48 are screwed with the screw holes 403 on the third side S3 of the panel installing member 40, so as to fix the first frame component 44 on the third side S3 of the panel installing member 40. In other words, the first frame component 44 can be fixed on the third side S3 of the panel installing member 40 by utilizing the screws 48, the through holes 441 and the screw holes 403. In addition, the screws 48 are disposed through the through holes 461 on the second frame component 46. Then, the screws 48 are screwed with the screw holes 405, so as to fix the second frame component 46 on the fourth side S4 of the panel installing member 40. In other words, the second frame component 46 can be fixed on the fourth side S4 of the panel installing member 40 by utilizing the screws 48, the through holes 461 and the screw holes 405. In such a manner, the first frame component 44 can be screwed on the panel installing member 40 cooperatively with the second frame component 46, as shown in FIG. 6.

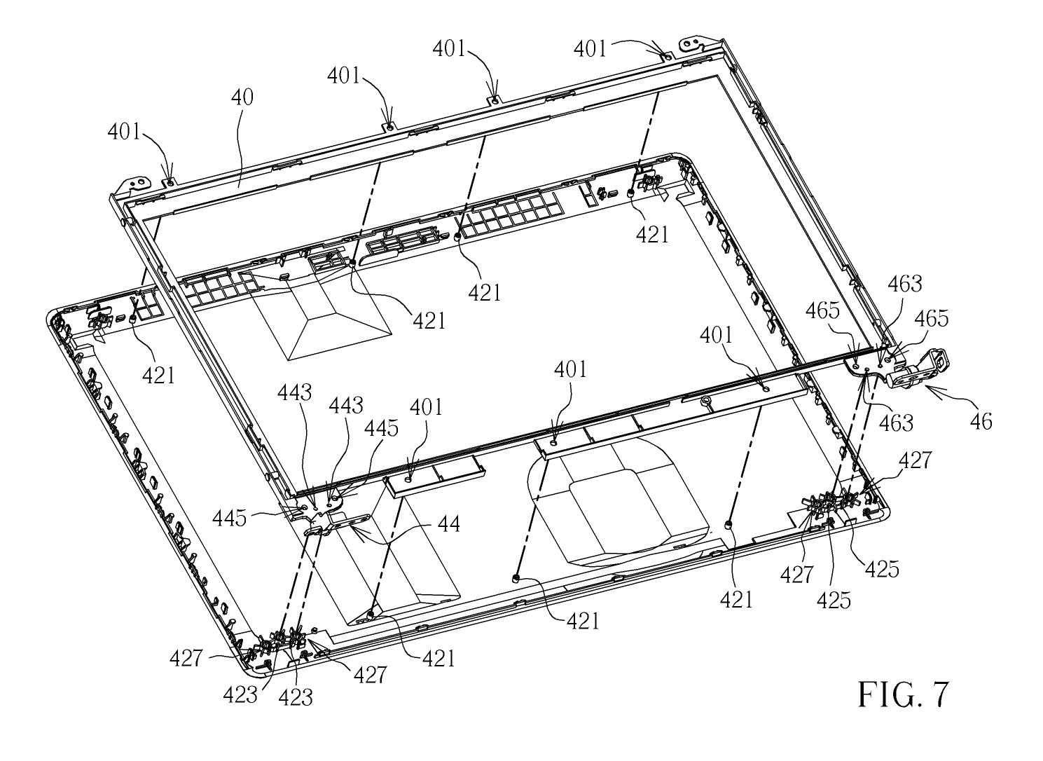

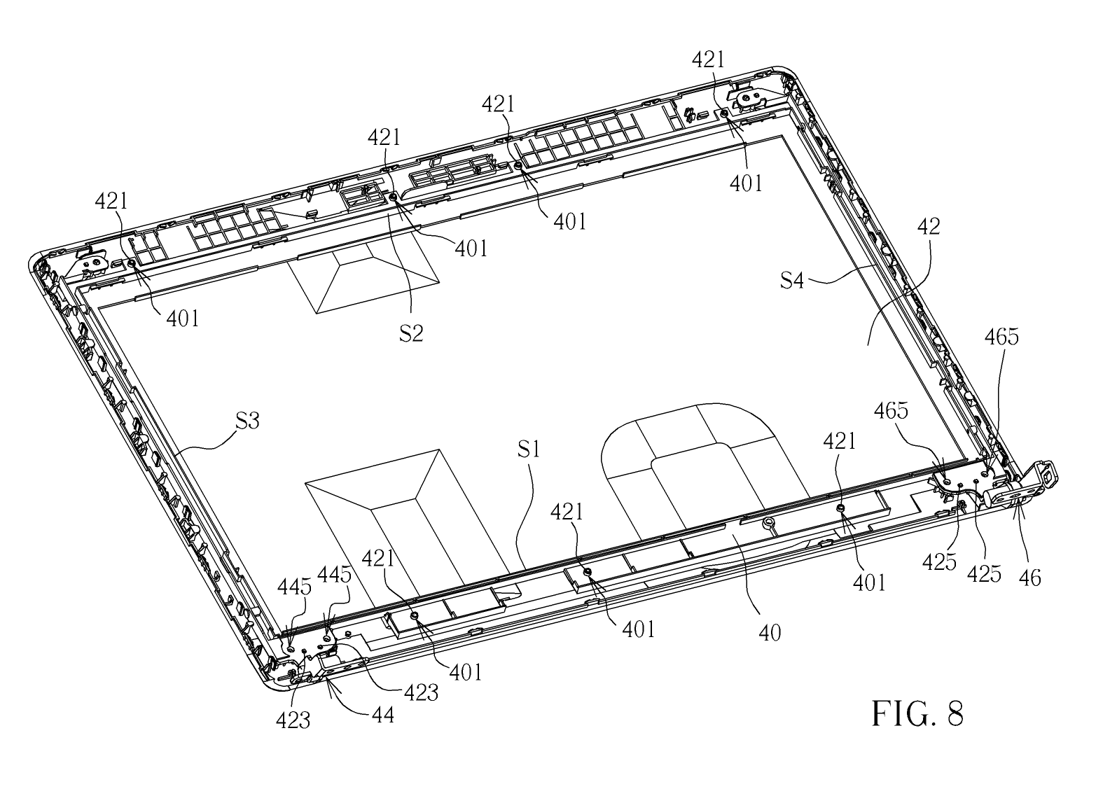

Please refer to FIG. 2, FIG. 4, FIG. 5, FIG. 7 and FIG. 8. FIG. 7 is an exploded diagram of the first frame component 44 screwed on the panel installing member 40 cooperatively with the second frame component 46 and the back cover 42 in FIG. 6. FIG. 8 is an assembly diagram of the components in FIG. 7. As shown in FIG. 2, FIG. 4, FIG. 5, FIG. 7 and FIG. 8, when the first frame component 44, the second frame component 46 and the first frame component 44 are assembled as shown in FIG. 6, the first positioning portion 443 and the first fixing portion 445 of the first frame component 44 as well as the second positioning portion 463 and the second fixing portion 465 of the second frame component 46 are respectively utilized for installing the first frame component 44 and the second frame component 46 on the back cover 42. At the same time, each of the posts 421 of the back cover 42 is disposed through the corresponding assembly hole 401 on the panel installing member 40, as shown in FIG. 8. Then, the first frame component 44 and the second frame component 46 are screwed on the back cover 42, and the first side S1 and the second side S2 of the panel installing member 40 are fixed on the back cover 42 in a hot melting manner. Finally, the panel installing member 40 is utilized for supporting the first panel module 36, so as to install the first panel module 36 on the back cover 42, as shown in FIG. 2. In such a manner, installation between the first panel module 36 and the assembly structure 38 of the panel device 34 is completed. It should be noticed that during process of installation between the first panel module 36 and the back cover 42, a shock absorption part, such as a sponge, can be disposed between the first panel module 36 and the back cover 42, so as to prevent the panel device 34 from damage due to collision of the portable electronic device 30 when being crashed. In addition, the first panel module 36 can be attached to the back cover 42 in a glue manner, so as to fix a relative position between the first panel module 36 and the back cover 42.

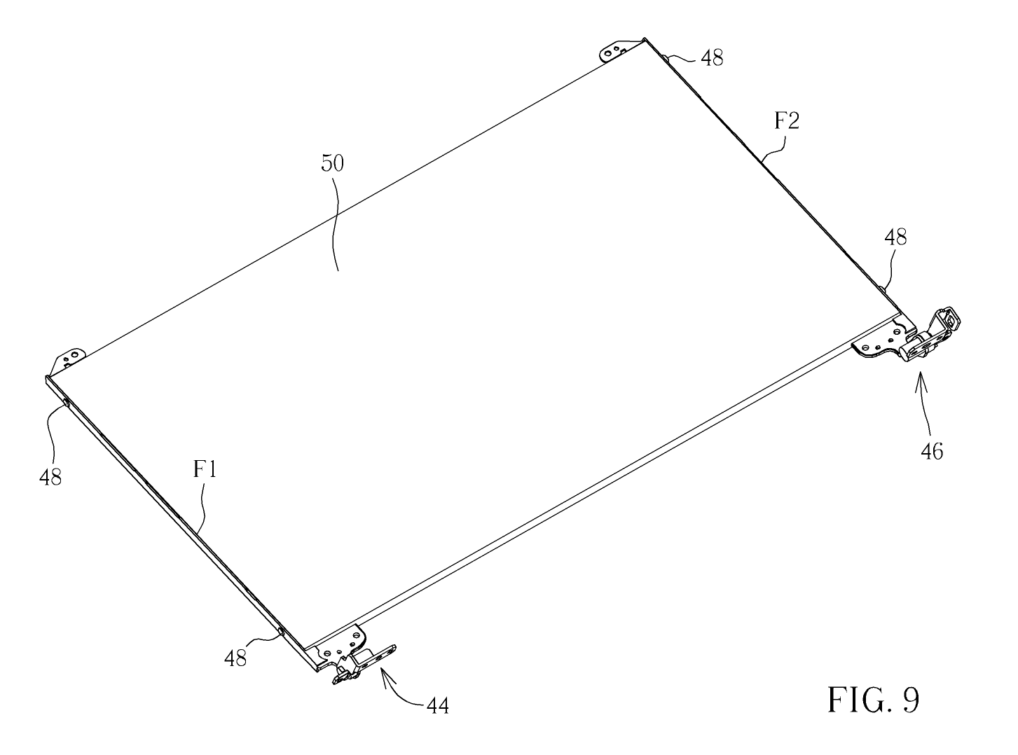

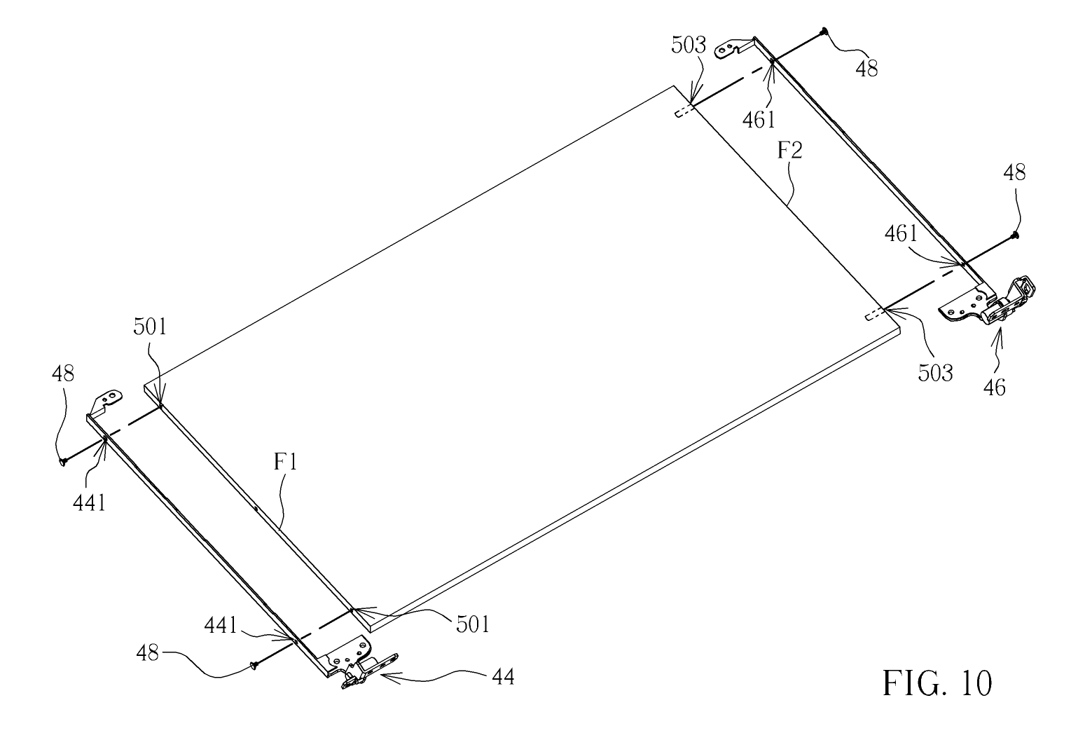

On the other hand, the assembly structure 38 of the present invention is used for installing a second panel module 50 with a different size from a size of the first panel module 36. In this embodiment, the size of the second panel module 50 is greater than that of the first panel module 36, and the panel installing member 40 is omitted when the assembly structure 38 is used for installing the second panel module 50. Please refer to FIG. 9 and FIG. 10. FIG. 9 is a diagram of the first frame component 44, the second frame component 46 and the second panel module 50 according to the embodiment of the present invention. FIG. 10 is an exploded diagram of the first frame component 44, the second frame component 46 and the second panel module 50 according to the embodiment of the present invention. As shown in FIG. 9 and FIG. 10, two screw holes 501 are formed on a first side F1 of the second panel module 50, and two screw holes 503, as shown in dotted lines in FIG. 10, are formed on a second side F2 of the second panel module 50 as well. In this embodiment, the two screw holes 501 on the first side F1 respectively correspond to the two through holes 441 on the first frame component 44. The two screw holes 503 on the second side F2 respectively correspond to the two through holes 461 on the second frame component 46 as well.

When assembling the first frame component 44, the second frame component 46 and the second panel module 50, the screws 48 can be screwed with the screw holes 501 on the first side F1 of the second panel module 50 after passing through the through holes 441 on the first frame component 44, so as to fix the first frame component 44 on the first side F1 of the second panel module 50. In other words, the first frame component 44 can be fixed on the first side F1 of the second panel module 50 by the screws 48, the through holes 441 and the screw holes 501. Then, the screws 48 can be screwed with the screw holes 503 on the second side F2 of the second panel module 50 after passing through the through holes 461 on the second frame component 46, so as to fix the second frame component 46 on the second side F2 of the second panel module 50. In other words, the second frame component 46 can be fixed on the second side F2 of the second panel module 50 by the screws 48, the through holes 461 and the screw holes 503. In such a manner, the first frame component 44 of the present invention can be screwed on the second panel module 50 cooperatively with the second frame component 46, as shown in FIG. 9.

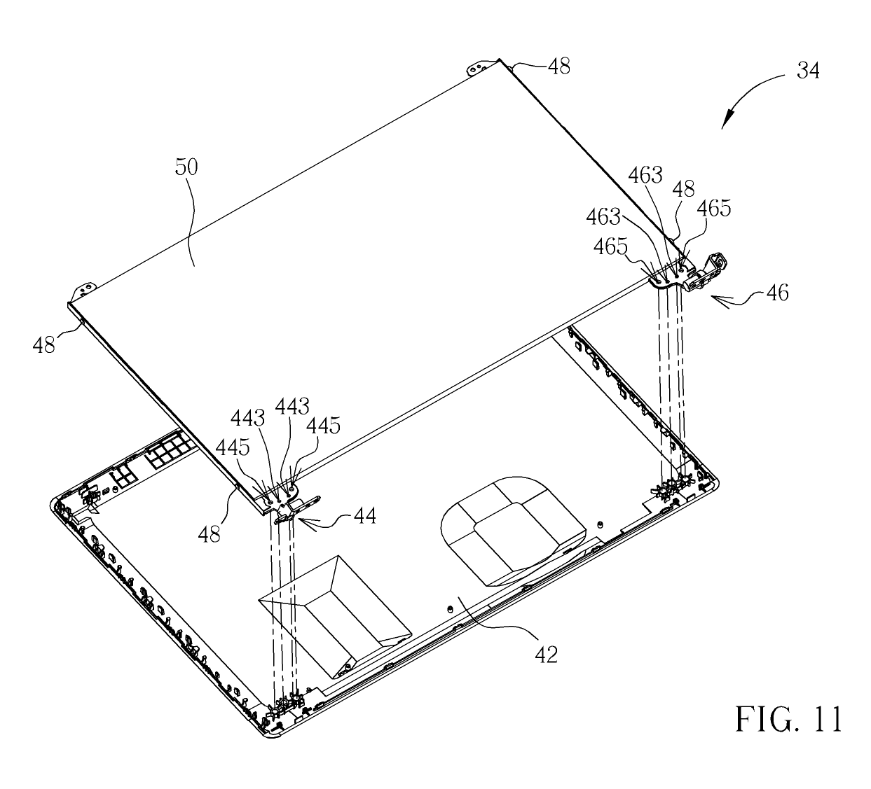

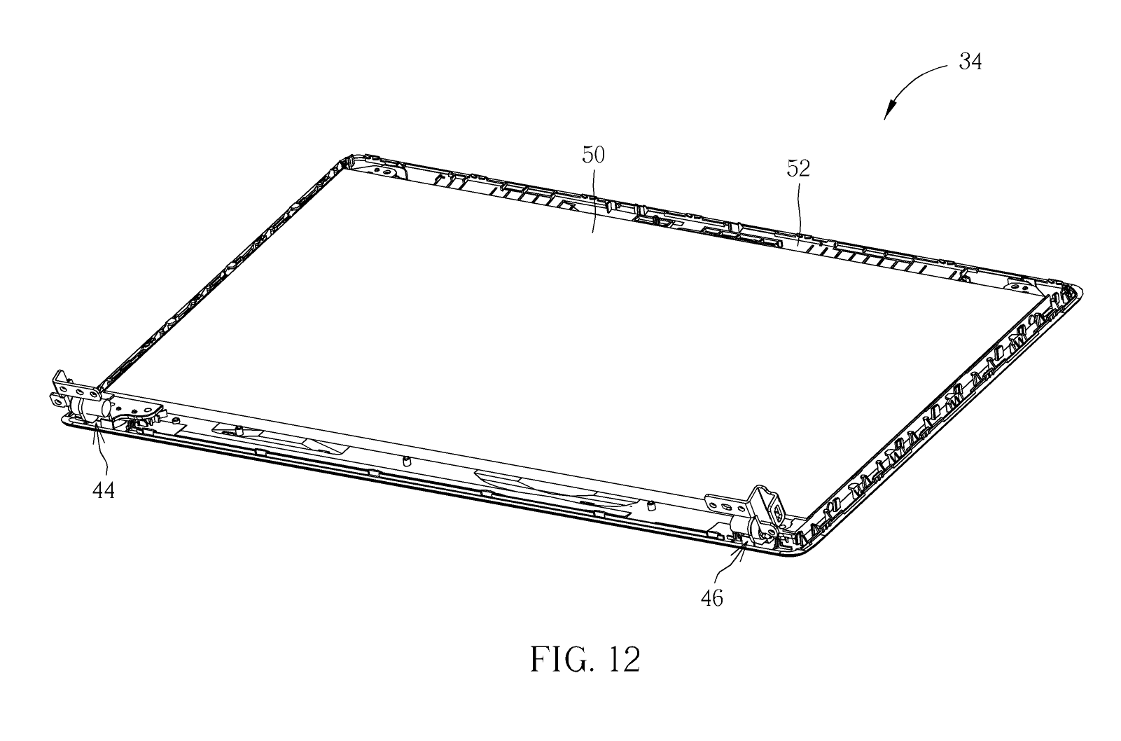

Please refer to FIG. 9, FIG. 11 and FIG. 12. FIG. 11 is an exploded diagram of the first frame component 44 screwed on the second panel module 50 cooperatively with the second frame component 46 and the back cover 42 in FIG. 9. FIG. 12 is an assembly diagram of the components in FIG. 11. As shown in FIG. 9, FIG. 11 and FIG. 12, when the first frame component 44, the second frame component 46 and the second panel module 50 are assembled as shown in FIG. 9, the first positioning portion 443 and the first fixing portion 445 of the first frame component 44 as well as the second positioning portion 463 and the second fixing portion 465 of the second frame component 46 are respectively utilized for installing the first frame component 44 and the second frame component 46 on the back cover 42, as shown in FIG. 11. Then, the first frame component 44 and the second frame component 46 can be screwed on the back cover 42, as shown in FIG. 12. In such a manner, installation between the second panel module 50 and the assembly structure 38 of the panel device 34 can be completed.

Compared to the prior art, when installing the first panel module, the assembly structure of the present invention utilizes the panel installing member, the first frame component and the second frame component to fix the first panel module on the back cover. On the other hand, when installing the second panel module with a different size, the assembly structure of the present invention only utilizes the first frame component and the second frame component, without utilizing the panel installing member, to fix the second panel module on the back cover. In such a manner, the assembly structure of the present invention allows the first panel module or the second panel module to be installed on the same back cover by selectively utilizing the panel installing member. In other words, the panel installing member can be an assembly structure for the panel modules with different sizes. Accordingly, the first panel module and the second panel module of the panel device of the present invention can be installed on the same back cover. In practical application, the present invention can prevent a plurality of tooling from manufacturing, so as to greatly reduce manufacturing costs and to result in advantage of the product in price.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An assembly structure for selectively assembling a first panel module and a second panel module with different sizes, comprising:
a panel installing member for holding a first panel module and having a plurality of assembly holes formed thereon;
a back cover comprising a plurality of posts, each of the posts being disposed through the corresponding assembly hole;
a first frame component installed on the back cover for being selectively fixed on a side of the panel installing member or on a side of a second panel module; and
a second frame component installed on the back cover for being selectively fixed on another side of the panel installing member or on another side of the second panel module, so as to fix the first panel module or the second panel module on the back cover cooperatively with the first frame component.

2. The assembly structure of claim 1, wherein the first frame component and the second frame component are screwed on the back cover, respectively.

3. The assembly structure of claim 1, wherein the first frame component and the second frame component are screwed on the panel installing member or on the second panel module, respectively.

4. The assembly structure of claim 1, wherein the plurality of posts is fixed inside the plurality of assembly holes in a hot melting manner, respectively.

5. A panel device, comprising:
a first panel module; and
an assembly structure for assembling the first panel module, comprising:
a panel installing member for holding a first panel module and having a plurality of assembly holes formed thereon;
a back cover comprising a plurality of posts, each of the posts being disposed through the corresponding assembly hole;
a first frame component installed on the back cover for being selectively fixed on a side of the panel installing member or on a side of a second panel module; and
a second frame component installed on the back cover for being selectively fixed on another side of the panel installing member or on another side of the second panel module, so as to fix the first panel module or the second panel module on the back cover cooperatively with the first frame component.

6. The panel device of claim 5, wherein the first frame component and the second frame component are screwed on the panel installing member, respectively.

7. The panel device of claim 5, wherein the first frame component and the second frame component are screwed on the panel installing member or on the second panel module, respectively.

8. The panel device of claim 5, wherein the first frame component and the second frame component are screwed on the back cover, respectively.

9. The panel device of claim 5, wherein the plurality of posts is fixed inside the plurality of assembly holes in a hot melting manner, respectively.
